(19) United States
(12) Patent Application Publication
(10) Pub. No.: US 2004/0013817 A1
(43) Pub. Date: Jan. 22, 2004

(54) Substrate processing method and substrate processing apparatus

(76) Inventors: Yoji Mizutani, Tokyo (JP); Masao Yamaguchi, Tokyo (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/617,812

(22) Filed: Jul. 14, 2003

Related U.S. Application Data
(63) Continuation-in-part of application No. PCT/JP02/00268, filed on Jan. 17, 2002.

(30) Foreign Application Priority Data
Jan. 19, 2001 (JP) JP2001-12384
Feb. 7, 2001 (JP) JP2001-30940

(51) Int. Cl. C23C 16/00

(52) U.S. Cl. 427/569; 427/402; 427/596; 118/712; 427/255.28

(57) ABSTRACT

An object of the present invention is to form an interlayer insulating film on a substrate and cure the interlayer insulating film in a time shorter than that in the prior art. The present invention is a substrate processing method in which the interlayer insulating film formed on the substrate is irradiated with electron beams in a processing chamber, whereby the interlayer insulating film is cured.

This application is a continuation-in-part of International Application No. PCT/JP02/00268 filed on Jan. 17, 2002.

### BACKGROUND OF THE INVENTION

1. Field of the Invention

The present invention relates to a substrate processing method and a substrate processing apparatus.

2. Description of the Related Art

In manufacturing processes of a semiconductor device in a multilevel interconnection structure, a process of forming an interlayer insulating film on a wafer and thereafter processing the interlayer insulating film is performed. The interlayer insulating film is an insulating film having electrical insulation performance in the multilevel interconnection structure, and, for example, MSQ (methyl silsesquioxane) or HSQ (hydrogen silsesquioxane) is used as its insulating material.

The processing on the interlayer insulating film is performed in, for example, an SOD (Spin on Dielectric) unit, which employs a film forming method such as a sol-gel method, silk method, speed film method, fox method, and the like, in which the interlayer insulating film is formed by applying a coating solution such as the aforementioned MSQ or the like to a wafer surface. In the aforementioned methods other than the sol-gel method, after the formation of the interlayer insulating film on the wafer, curing processing of curing the interlayer insulating film is performed in order to raise the selection ratio of an etching object material.

This curing processing is processing which brings the interlayer insulating film a polymerization reaction such as polymerization, and hitherto performed by heating a wafer at a high temperature. Since extremely high energy is required to induce the polymerization reaction, the curing processing is performed in a heating furnace capable of heating the wafer at a high temperature. Moreover, a long time is needed to carry out the sufficient polymerization reaction by heat energy as described above, whereby a batch-type large-sized heating furnace capable of heating plural wafers at a time is used for the curing processing from the viewpoint of throughput. In the curing processing, thermal energy generated by heating causes a polymerization reaction of the insulating material MSQ such as polymerization and cross linking to cure the interlayer insulating film.

However, the curing processing in the heating furnace, usually performed at a temperature as high as about 500° C., has required a long time, about 30 minutes to about 60 minutes, for completion of the polymerization reaction of MSQ or the like even at such a high temperature. Such a long time required for the curing processing makes it difficult to reduce the wafer processing time required for producing various kinds of items and variable quantity production, that is, realize a reduction in TAT(Turn Around Time). In addition, the processing at a high temperature presents a disadvantage that insulating materials susceptible to high temperatures cannot be employed.

Besides, since plural wafers are processed at a time in the curing processing in the heating furnace, wafers early formed with insulating films have to wait subsequent wafers (in other words, “waiting time” is generated), which varies a total processing time between formation and cure of the insulating film for each wafer. Therefore, thermal histories vary among the wafers, for example, when heating processing for once vaporizing a solvent is performed after coating, which may generate variation in quality of the interlayer insulating films.

Further, the curing processing in the heating furnace is performed in a minimum time for completion of the polymerization reaction in order to improve the throughput, and thus the polymerization reaction may not be sufficiently performed in a deep portion of the interlayer insulating film when the interlayer insulating film has a large film thickness.

### SUMMARY OF THE INVENTION

The present invention is made in view of the aforementioned point, and its object is to perform the aforementioned curing processing in a shorter time and at a lower temperature and reduce the total processing time of a substrate such as a wafer or the like to thereby realize a reduction in TAT (Turn Around Time).

The present invention is a substrate processing method comprising the steps of: forming an interlayer insulating film on a substrate; and irradiating the interlayer insulating film on the substrate with electron beams in a processing chamber to cure the interlayer insulating film.

In the present invention, in the step of curing the interlayer insulating film, the substrate may be heated to a predetermined temperature. Besides, the step of curing the interlayer insulating film may be performed in a reduced oxygen atmosphere with an oxygen concentration lower than that of at least an atmospheric air. In this case, the atmosphere around the substrate may be replaced with a gas of molecular weight lower than that of oxygen.

In the present invention, the pressure in the processing chamber may be controlled in irradiating with the electron beams.

In the present invention, a pre-heating step of heating the substrate may be performed after the substrate is coated with a coating solution which becomes the interlayer insulating film and before cure of the interlayer insulating film by irradiation with the electron beams. In this case, the period of time between completion of the pre-heating step and irradiation of the substrate with the electron beams may be controlled to be constant. Further, the pre-heating may be performed at a temperature lower than a temperature of the substrate in the step of curing the interlayer insulating film.

In the present invention, plasma may be generated in the processing chamber after irradiating with the electron beams to cure the interlayer insulating film.

In another viewpoint, the present invention is a substrate processing method comprising the steps of: repeating both a coating step of coating the substrate with a coating solution which becomes the interlayer insulating film and a pre-heating step of heating the substrate after the coating step; and after a final coating step, irradiating a plurality of interlayer insulating films on the substrate with electron beams in a processing chamber to concurrently cure the plurality of interlayer insulating films.

In the present invention, the irradiation with the electron beams enables effective irradiation of an object to be irradiated with electron beams having extremely high energy. Therefore, by irradiating the interlayer insulating film on the substrate with the electron beams with high energy, the polymerization reaction of the interlayer insulating film is started in a short time and the curing speed of the interlayer insulating film is increased. This greatly reduces the curing processing time and also reduces the total processing time. Besides, since it is unnecessary to heat to a high temperature as in the prior art, the curing processing can be performed at a relatively low temperature, thus allowing use of an insulating material with a low heat resistance. Furthermore, the irradiation with the electron beams can be performed in a single substrate processing system, thus keeping almost constant the total processing time between formation of the interlayer insulating film and curing processing. Besides, the electron beams, which are excellent in penetration, can perform uniform curing processing even when the interlayer insulating film has a large thickness.

Besides, if the irradiation with the electron beams is performed in a reduced oxygen atmosphere with an oxygen concentration lower than that of at least an atmospheric air, it becomes possible to restrain emitted electron beams from scattering and losing energy due to the electron beams colliding with oxygen molecules.

When the reduced oxygen atmosphere is created by replacing an atmosphere around the substrate with a gas of molecular weight lower than that of oxygen, it is possible to restrain scattering of the electron beams caused by an electric field created by the oxygen molecules so that the curing processing is preferably performed on the interlayer insulating film. Note that examples of the gas of molecular weight lower than that of oxygen include, for example, helium, nitrogen, and the like.

Alternatively, the reduced oxygen atmosphere may be created by reducing a pressure in the processing chamber. The reduction in the pressure of the processing chamber can reduce oxygen molecules and the like to restrain scattering of emitted electron beams.

In still another viewpoint, the present invention is a substrate processing method comprising the steps of: forming an insulating film on a substrate by a CVD process; and irradiating the insulating film on the substrate with electron beams in a processing chamber to process the insulating film. An insulating film is formed on the substrate by the CVD process in such a manner and then irradiated with electron beams so that the insulating film formed by CVD can be made stronger and better in quality.

In the present invention, a pre-heating is performed between the coating step and the step of curing the interlayer insulating film, whereby a solvent and the like remaining in the interlayer insulating film can be vaporized. This can prevent the solvent and the like from vaporizing due to receipt of high energy of the electron beams or the like in subsequent curing processing, thus preventing the curing processing from being inappropriately performed and the solvent from contaminating a light source of the electron beams.

In the present invention, the period of time between completion of the pre-heating step and irradiation of the substrate with the electron beams is controlled to be constant, whereby thermal histories of substrates from the pre-heating to the irradiation with the electron beams become uniform. This restrains variations in thermal histories among substrates so that a predetermined amount of heat is provided to each substrate, resulting in formation of appropriate insulating films having a uniform quality.

In the present invention, post-heating is performed after the curing processing of the interlayer insulating film, whereby it is possible to recover from damage at a lower region of the interlayer insulating film due to the electron beams, so that the interlayer insulating film improves in insulation performance to form an interlayer insulating film of a better quality. In addition, polymerization can be accelerated.

In the present invention, plasma is generated in the processing chamber after the interlayer insulating film is cured by irradiation with electron beams, whereby the potential of a charged-up substrate can be lowered.

The present invention comprises the steps of repeating both a coating step of coating a substrate with a coating solution which becomes an interlayer insulating film and a pre-heating step of heating the substrate after the coating step; and after a final coating step, irradiating a plurality of interlayer insulating films on the substrate with electron beams in a processing chamber to concurrently cure the plurality of interlayer insulating films. Therefore, the plurality of interlayer insulating film can be cured in a time shorter than that in the prior art.

A substrate processing apparatus of the present invention comprises a first processing section having a coating unit for coating a substrate with a coating solution which becomes an insulating film, a second processing section having a curing processing unit for curing the insulating film on the substrate by irradiating the substrates one by one with electron beams; and a carrier mechanism for carrying the substrate between the first processing section and the second processing section.

In the substrate processing apparatus of the present invention, the curing processing unit may include a grid electrode between a mounting table on which the substrate is mounted and a device for irradiating with the electron beams.

In the substrate processing apparatus of the present invention, the curing processing unit may be structured such that the mounting table on which the substrate is mounted applies a reverse bias voltage to the substrate.

In the substrate processing apparatus of the present invention, the curing processing unit is structured such that the pressure in the curing processing unit may be allowed to be reduced.

In the substrate processing apparatus of the present invention, the first processing section may include a heating processing unit for subjecting the substrate coated with the coating solution to heating processing.

In the substrate processing apparatus of the present invention, the first processing section may include a resist coating unit for coating the substrate with a resist solution and a developing unit for subjecting the substrate to developing treatment, and an exposure processing unit for exposing the substrate may be provided in an area where the substrate is allowed to be carried by the carrier mechanism. In this case, an etching unit for subjecting the substrate to etching processing in a reduced pressure atmosphere may be provided in the second processing section.

The substrate processing apparatus of the present invention may include a carrier chamber housing the carrier mechanism and being hermetically closable; and a pressure reducing mechanism for reducing the pressure in the carrier chamber to a predetermined pressure.

In the substrate processing apparatus of the present invention, the pressure in the second processing section may be allowed to be reduced.

The substrate processing apparatus of the present invention may include a reduced pressure chamber housing the carrier mechanism and the second processing section and being hermetically closable; and a pressure reducing mechanism for reducing the pressure in the reduced pressure chamber to a predetermined pressure.

In the substrate processing apparatus of the present invention, a thermal processing unit for subjecting the substrate to thermal processing may be provided in the second processing section.

According to the substrate processing apparatus of the present invention, the substrates on each of which the insulating film is formed can be subjected to curing processing one by one, whereby a waiting time of the substrate before and after the curing processing can be eliminated, leading to a reduction in TAT of substrate processing. Moreover, the electron beam has extremely high energy as compared with conventional heat energy, whereby a polymerization reaction of an insulating material is carrier out in a short time, and as a result, the curing processing time can be greatly reduced. Hence, the substrate processing time is reduced, whereby a reduction in TAT is achieved. Further, by providing the carrier mechanism, the substrate can be carried smoothly between the first processing section and the second processing section, whereby its carriage to the curing processing unit is also performed appropriately, resulting in a reduction in TAT of substrate processing.

The aforementioned grid electrode can control the energy and the number of electrons of electron beams reaching the substrate. The mounting table on which the substrate is mounted applies a reverse bias voltage to the substrate, whereby the reaching distance of energy of electron beams reaching the inside of the substrate can be controlled.

In the present invention, when a resist coating unit for coating the substrate with a resist solution and a developing unit for subjecting the substrate to developing treatment are provided in the first processing section, and an exposure processing unit for exposing the substrate in an area where the substrate is allowed to be carried by the carrier mechanism is provided, it is possible that the substrate on which the insulating film is formed and which has undergone curing processing is returned to the first processing section again, coated with the resist solution, carried to the exposure processing unit by the carrier mechanism, subjected to exposure processing, thereafter returned to the first processing section, and subjected to developing treatment. Accordingly, a photolithography process of forming a resist film in a predetermined pattern can be performed in the substrate processing apparatus of the present invention, and the aforementioned series of processing can be inlined. As a result, it becomes unnecessary to carry the substrate to another processing apparatus which is separately provided, and the substrate processing time can be correspondingly reduced. By further providing an etching unit, the substrate which has undergone the aforementioned lithography process can be subjected to etching processing in the same processing apparatus, so that the process to the etching processing can be inlined, and hence the substrate processing time is further reduced.

The present invention further includes a carrier chamber housing the carrier mechanism and being hermetically closable and a pressure reducing mechanism for reducing the pressure in the carrier chamber to a predetermined pressure, it is possible to maintain a reduced pressure atmosphere in a carrier path when the substrate is carried between the first processing section and the second processing section and form a reduced oxygen atmosphere therein. Consequently, the oxidation of the coating solution or the like on the substrate during carriage is prevented. Furthermore, the pressure in the carrier chamber can be reduced to an intermediate pressure between the atmospheric pressure and the pressures in the curing processing unit and the etching unit, whereby the pressure difference between inside and outside the curing processing unit and the etching unit is reduced, resulting in the pressure reduction time of these units. By reducing the pressure on the substrate stepwise when the substrate is carried into the etching unit or the like in which the pressure is highly reduced, a burden imposed on the substrate due to pressure change can be lightened.

In the present invention, when the pressure of an atmosphere in the aforementioned second processing section is allowed to be reduced, a relatively low reduced pressure atmosphere can be maintained in the second processing section. Consequently, the pressure reduction time of the etching unit and the curing processing unit can be reduced.

In the present invention, when the substrate processing apparatus further includes a reduced pressure chamber housing the carrier mechanism and the second processing section and being hermetically closable, and a pressure reducing mechanism for reducing the pressure in the reduced pressure chamber to a predetermined pressure, it becomes possible to maintain a reduced pressure atmosphere in the carrier path when the substrate is carried between the first processing section and the second processing section and form a reduced oxygen atmosphere therein. Consequently, the oxidation of the coating solution or the like on the substrate is prevented. Furthermore, the pressure in the reduced pressure chamber can be reduced to an intermediate pressure between the atmospheric pressure and the pressures in the curing processing unit and the etching unit, whereby the pressure difference between inside and outside the curing processing unit and the etching unit is reduced, resulting in the pressure reduction time of these units.

### BRIEF DESCRIPTION OF THE DRAWINGS

FIG. 1 is an explanatory view of a horizontal section showing an outline of the structure of an insulating film forming apparatus in which a wafer processing method according to an embodiment is implemented;

FIG. 2 is a front view of the insulating film forming apparatus of FIG. 1;

FIG. 3 is a rear view of the insulating film forming apparatus of FIG. 1;

FIG. 4 is an explanatory view of a vertical section of a curing processing unit;

FIG. 5 is an explanatory view of a horizontal section showing another structure example of the insulating film forming apparatus;

FIG. 6 is an explanatory view of a horizontal section showing an outline of the structure of a wafer processing apparatus according to an embodiment;

FIG. 7 is a front view of the wafer processing apparatus in FIG. 6;

FIG. 8 is a rear view of the wafer processing apparatus in FIG. 6.

FIG. 9 is an explanatory view of a vertical section of a curing processing unit;

FIG. 10 is an explanatory view of vertical sections of wafers each showing a state in which a film is formed on the wafer in each processing step;

FIG. 11 is an explanatory view of a horizontal section showing an outline of the wafer processing apparatus when an etching unit is provided therein;

FIG. 12 is an explanatory view of a horizontal section showing an outline of a wafer processing apparatus including a reduced pressure chamber;

FIG. 13 is an explanatory view of a horizontal section showing an outline of the wafer processing apparatus when a sixth processing unit group is provided in a second processing station;

FIG. 14 is a rear view of the wafer processing apparatus showing the configuration of processing units in the wafer processing apparatus in FIG. 13;

FIG. 15 is an explanatory view of a vertical section showing a structure in which a grid electrode is placed in a curing processing unit;

FIG. 16 is an explanatory view of a vertical section showing a structure in which a plasma generator is provided in a curing processing unit; and

FIG. 17 is an explanatory view of a vertical section of an example of a plasma CVD unit usable in the present invention.

### DETAILED DESCRIPTION OF THE INVENTION

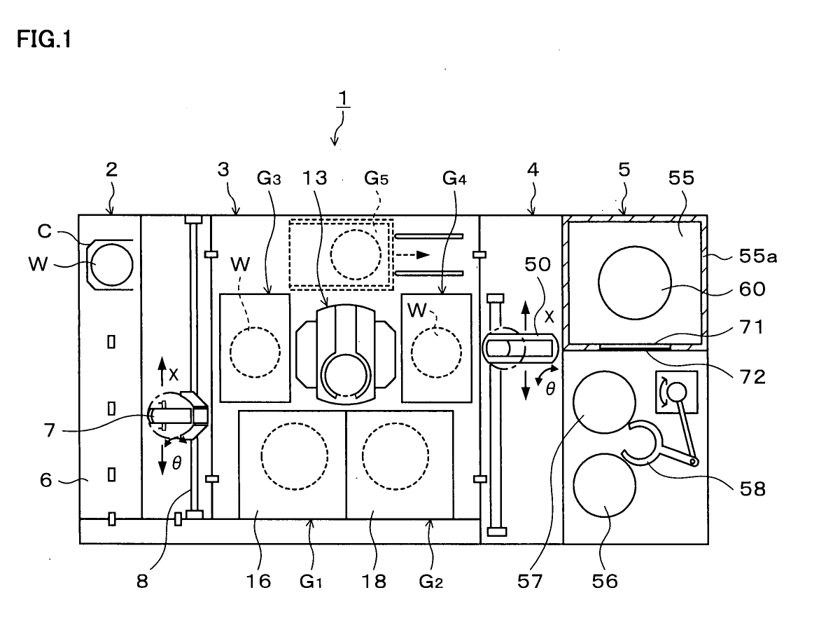

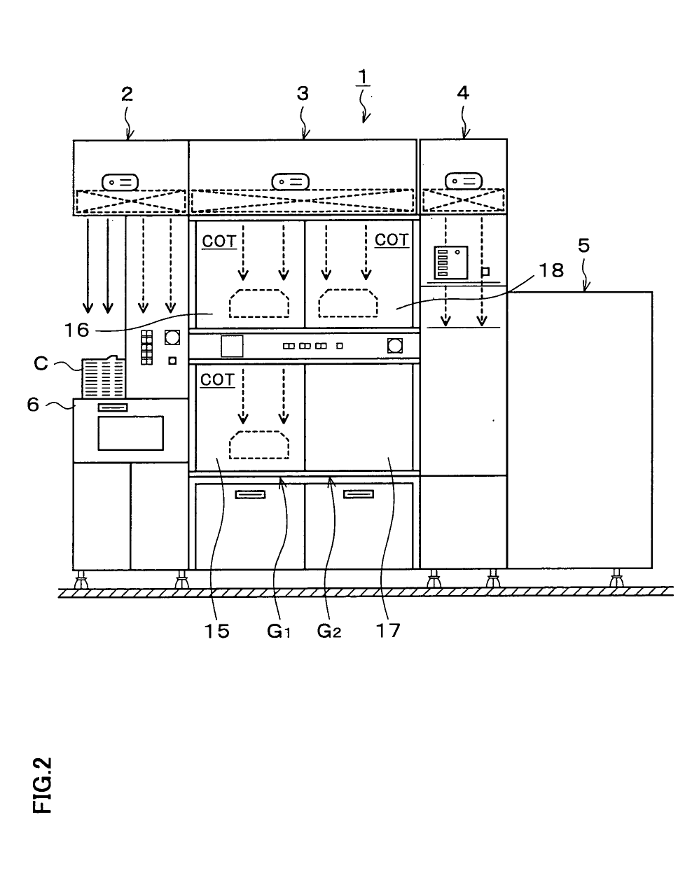

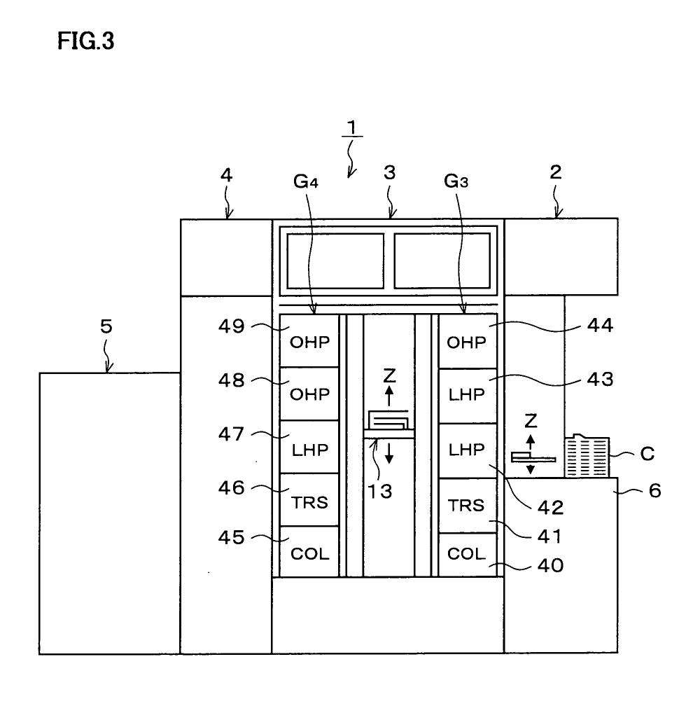

A preferred embodiment of the present invention will be explained below. FIG. 1 is a plan view showing an outline of an insulating film forming apparatus 1 in which a processing method of a wafer W according to this present embodiment is implemented, FIG. 2 is a front view of the insulating film forming apparatus 1, and FIG. 3 is a rear view of the insulating film forming apparatus 1.

As shown in FIG. 1, the insulating film forming apparatus 1 has a structure in which a cassette station 2 for carrying, for example 25 wafers W per cassette, as a unit, from/to the outside into/out of the insulating film forming apparatus 1 and carrying the wafers W into/out of a cassette C, a first processing station 3 including various kinds of processing units for performing predetermined processing in a single wafer processing system in an insulating film forming process, an interface section 4 provided adjacent to the first processing station 3 for transferring the wafers W, and a second processing station 5 including an undermentioned curing processing unit 55 for performing curing processing of an interlayer insulating film, are integrally connected.

In the cassette station 2, a plurality of cassettes C can be mounted at predetermined positions on a cassette mounting table 6, which is a mounting portion, in a line in an X-direction (a top-to-bottom direction in FIG. 1). A wafer carrier 7 which is movable in the direction of arrangement of the cassettes (the X-direction) and in the direction of arrangement of the wafers W housed in the cassette C (a Z-direction; a vertical direction) is provided to be freely movable along a carrier path 8 so as to be able to selectively get access to the respective cassettes C.

The wafer carrier 7 has an alignment function for aligning the wafers W. The wafer carrier 7 is also structured to be able to get access to a transfer unit 41 included in a third processing unit group G3 on the undermentioned first processing station 3 side.

In the first processing station 3, a main carrier 13 is provided at the center thereof, and various kinds of the processing units are stacked in multiple tiers around the main carrier 13 to constitute processing unit groups.

In the insulating film forming apparatus 1, four processing unit groups G1, G2, G3, and G4 are placed, the first and second processing unit groups G1 and G2 are placed on the front side of the insulating film forming apparatus 1, the third processing unit group G3 is placed adjacent to the cassette station 2, and the fourth processing unit group G4 is placed adjacent to the interface station 4. Further, a fifth processing unit group G5 shown by a broken line can be additionally placed on the rear side as an option. The main carrier 13 can carry the wafers W into/out of the undermentioned various processing units which are placed in these processing unit groups G1, G2, G3, and G4. It should be noted that the number and the placement of processing unit groups are different depending on the type of treatment and processing given to the wafers W, and the number of processing unit groups can be arbitrarily selected.

In the first processing unit group G1, as shown in FIG. 2, coating units 15 and 16 for applying a coating solution, which becomes an insulating film, to the wafers W, are stacked in two tiers. In the second processing unit group G2, a chemical chamber 17 including buffer tanks of chemicals and so on and a coating unit 18, are stacked in two tiers.

In the third processing unit group G3, for example, as shown in FIG. 3, a cooling unit 40 for cooling the wafer W, a transfer unit 41 for transferring the wafer W from/to the cassette station 2, low temperature heating units 42 and 43 for heating the wafer W at a lower temperature, a high temperature heating unit 44 for heating the wafer W at a high temperature, and the like, are, for example, stacked in five tiers from the bottom in order.

In the fourth processing unit group G4, for example, a cooling unit 46, a transfer unit 46 for transferring the wafer W to/from the interface section 4, a low temperature heating unit 47, high temperature heating units 48 and 49, and the like, are, for example, stacked in five tiers from the bottom in order. It should be noted that pre-heating before curing processing is performed at two stages in the low temperature heating unit 42, 43, or 47 and the high temperature heating unit 44, 48, or 49.

In the interface section 4, a wafer carrier 50 is provided. The wafer carrier 50 is structured to be movable in the X-direction (the top-to-bottom direction in FIG. 1) and in the Z-direction (the vertical direction) and rotatable in a θ-direction (a direction of rotation around a Z-axis) so as to be able to get access to the transfer unit 46 included in the fourth processing unit group G4 and undermentioned mounting portions 56 and 57 in the second processing station 5.

The second processing station 5 is provided adjacent to the interface section 4. The second processing station includes a curing processing unit 55 in which curing processing is performed on an interlayer insulating film, the mounting portions 56 and 57 for once mounting thereon the wafers W which are carried between the interface section 4 and the curing processing unit 55, and a carrier arm for carrying the wafer W between the mounting portions 56 and 57 and the curing processing unit 55.

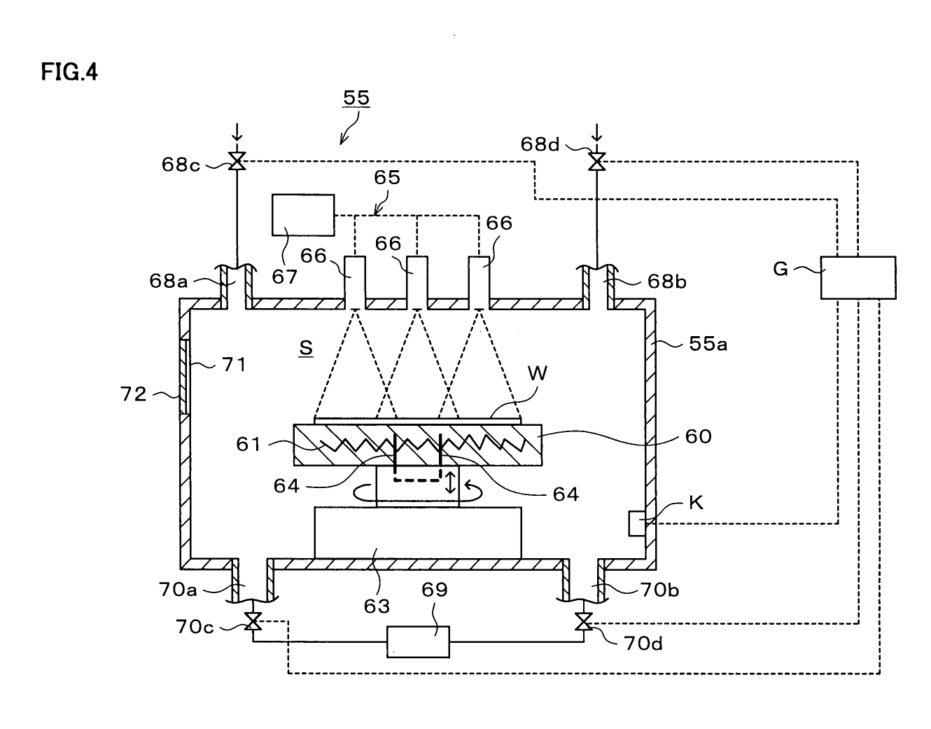

Next, the structure of the aforementioned curing processing unit 55 will be described in detail. FIG. 4 is an explanatory view of a vertical section showing the outline of the structure of the curing processing unit 55.

The curing processing unit 55 includes a casing 55a which covers all of the unit to form a processing chamber S, whereby a predetermined atmosphere can be maintained in the curing processing unit 55. A mounting table 60 on which the wafer W is mounted is placed in the middle of the casing 55a. The mounting table 60 takes the shape of a thick disc shape, and a material having excellent thermal conductivity, for example, silicon carbide, aluminum nitride, or the like which is ceramic is used as its material.

The mounting table 60 contains a heating means for raising the temperature of the mounting table 60, for example, a heater 61. The heating value of the heater 61 is controlled by a controller not shown, whereby the temperature of the mounting table 60 can be maintained at a predetermined temperature.

A drive mechanism 63 including a rotation means for allowing the mounting table 60 to be rotatable, for example, a motor or the like is placed under the mounting table 60. Hence, it becomes possible to rotate the mounting table 60 at the time of irradiating with electron beams from undermentioned electron beam tubes 66 to thereby uniformly irradiate the entire surface of the wafer W on the mounting table 60 with the electron beams. Incidentally, the drive mechanism 63 may be provided with a raising and lowering mechanism which allows the mounting table 60 to be vertically movable, as a distance adjustment means for enabling adjustment of the distance with respect to the undermentioned electron beam tubes 66.

The mounting table 60 is provided with a plurality of, for example, three raising and lowering pins 64 which are protrudable above the mounting table 60 and raise and lower the wafer W while supporting it. This allows the raising and lowering pins 64 to rise and receive the wafer W and the raising and lowering pins 64 to lower and mount the wafer W on the mounting table 60.

The curing processing unit 55 includes an irradiation device 65 for irradiating the wafer W on the mounting table 60 with electron beams. The irradiation device 65 includes plural electron beam tubes 66 each for applying an electron beam and an irradiation controller 67 for controlling output of the electron beams and irradiation time. The electron beam tubes 66 are arranged in positions facing the mounting table 60 in an upper surface of the casing 55a, so that the electron beams can be applied to the interlayer insulating film from above the wafer W. The electron beam from each of the electron beams tubes 66 widens as it approaches the wafer W, and the entire face of the wafer W is can be irradiated with the electron beams by irradiation from all of the electron beam tubes 66.

In the upper surface of the casing 55a, supply pipes 68a and 68b for supplying gas other than oxygen, for example, an inert gas, helium gas, nitrogen gas, or the like are provided. The supply pipe 68a is provided on the side of an undermentioned carrier opening 71, and the supply pipe 68b is provided on the opposite side of the undermentioned carrier opening 71. This enables the inert gas from a not-shown supply source to be supplied into the casing 55a and substituted in the casing 55a, which creates a reduced oxygen atmosphere in which curing processing is performed. Moreover, the supply pipes 68a and 68b are provided with valves 68c and 68d for regulating the supply quantity of the inert gas, respectively, whereby the supply quantity of the inert gas to be supplied into the casing 55a can be regulated. On the other hand, in a lower surface of the casing 55a, exhaust pipes 70a and 70b which are connected to a suction pump 69 placed outside the curing processing unit 55 are provided to be able to purge the inside of the casing 55a.

The exhaust pipes 70a and 70b are provided with valves 70c and 70d for regulating exhaust quantity, respectively. The aforementioned valves 68c and 68d and 70c and 70d are structured in such a manner that their opening and closing can be operated by a control part G. In the casing 55a, a detection sensor K for detecting the barometric pressure and oxygen concentration in the casing 55a, and obtained detected data can be transmitted to the control part G. Such a structure makes it possible that the data detected by the detection sensor K is transmitted to the control part G and that the control part G operates the valves 68c and 68d and valves 70c and 70d based on the data. Accordingly, the supply quantity of the inert gas to be supplied into the casing 55a and the exhaust quantity to be exhausted to the outside of the casing 55a can be regulated, whereby the barometric pressure and oxygen concentration in the casing 55a can be controlled at predetermined values. Moreover, when the wafer W is carried in/out through the carrier opening 71, the supply quantity from the supply pipe 68a on the carrier opening 71 side can be increased, which makes it possible to compensate for the inert gas which has leaked from the carrier opening 71 and thereby maintain the predetermined atmosphere in the casing 55a.

The carrier opening 71 for carrying the wafer W in/out therethrough is placed on the carrier arm 58 side of the casing 55a. This carrier opening 71 is provided with a shutter 72 which makes the carrier opening 71 openable and closable. This allows the atmosphere in the casing 55a to be cut off from the external atmosphere to maintain the predetermined atmosphere in the casing 55a.

Next, a processing process of the wafer W, which is performed in the insulating film forming apparatus 1 structured as above will be explained.

First, a wafer W taken out of the cassette station 2 by the wafer carrier 7 is carried to the transfer unit 42, and carried therefrom by the main carrier 13 into the cooling unit 41 which controls temperature. Then, the wafer W is carried by the main carrier 13 to the coating unit 15, 16, or 18 where the wafer W is coated with a predetermined coating solution which becomes an interlayer insulating film, for example, a coating solution containing MSQ. The coating processing is performed, for example, by rotating the wafer at a predetermined speed and supplying the coating solution to the center part of the rotated wafer W, in which the supplied coating solution is spread over the entire face of the wafer W by centrifugal force.

Then, the wafer W coated with the coating solution is carried, for example, to the low temperature heating unit 42, where the wafer W is subjected to heating processing, for example, at 150° C. for two minutes. Thereafter, the wafer W is carried to the high temperature heating unit 48, where the wafer W is heated, for example, at 200° C. for one minute. By the pre-heating in the low temperature heating unit 42 and high temperature heating unit 48, the solvent in the coating solution is removed by vaporization, and an interlayer insulating film is formed on the wafer W.

Next, the wafer W is carried by the main carrier 13 to the transfer unit 46. Then, the wafer W is carried by the wafer carrier 50 in the interface section 4 to the mounting portion 57 in the second processing station 5. Subsequently, the wafer W is held by the carrier arm 58 and carried into the curing processing unit 55 concurrently with opening of the shutter 72 of the curing processing unit 55.

Here, operation of the curing processing unit 55 which performs curing processing on the interlayer insulating film on the wafer W will be described. First, before the wafer W is carried into the curing processing unit 55, the heating value of the heater 61 is controlled by, for example, the controller not shown, whereby the temperature of the mounting table 60 is maintained, for example, at 250° C. which is higher than the heating temperature of the aforementioned high temperature heating unit 48.

Then, when being carried into the casing 55a through the carrier opening 71 by the carrier arm 58, the wafer W is moved to a position above the center portion of the mounting table 60 and transferred to the raising and lowering pins 64 which rise and stand by in advance. Thereafter, the carrier arm 58 withdraws from within the casing 55a, and the shutter 72 is closed. Subsequently, the wafer W is lowered with the lowering of the raising and lowering pins 64 and mounted on the mounting table 60. This starts raising the temperature of the wafer W At this time, helium gas, for example, is supplied into the casing 55a from the supply pipes 68a and 68b, and the atmosphere in the casing 55a is exhausted from the exhaust pipes 70a and 70b. Consequently, the helium gas is substituted in the casing 55a. Then, the detection sensor K monitors the oxygen concentration in the casing 55a, and the control part G operates based on the detected data the valves 68c and 68d and valves 70c and 70d. As a result, an atmosphere with a low oxygen concentration, for example, an oxygen concentration of 3 ppm or lower is maintained in the casing 55a. It should be noted that the valve 68c may be adjusted to increase the supply quantity of the helium gas from the supply pipes 68 when the wafer W is carried in/out.

When the temperature of the wafer W on the mounting table 60 is stabilized at 250° C. after a lapse of a predetermined period of time, the wafer W is rotated at a low speed by the drive mechanism 63. Thereafter, as shown in FIG. 4, the interlayer insulating film on the surface of the wafer W is irradiated with an electron beam at a predetermined output, for example, 10 keV, from each of the electron beam tubes 66 for a predetermined period of time, for example, two minutes. Hence, energy of the electron beams is supplied to the interlayer insulating film to induce macromolecular polymerization of MSQ (methyl silsesquioxane) which forms the interlayer insulating film, and thereby the interlayer insulating film is cured. Incidentally, the output of the electron beams and irradiation time in this event are set according to film thickness, processing atmosphere, and the like.

When the irradiation with electron beams for two minutes is completed, the rotation of the mounting table 60 is stopped, and the mounting table 60 is raised again by the raising and lowering pins 64. At that time, the supply and exhaust of the helium gas is stopped. Then, the shutter 72 is opened, the carrier arm 58 goes into the casing 55a, and the wafer W is transferred to the carrier arm 58.

Subsequently, the wafer W is carried from the curing processing unit 55 to the mounting portion 56 and mounted thereon. Then, the wafer W is carried, for example, by the wafer carrier 50 and the main carrier 13 to the cassette station 2 to be returned to the cassette C, and a series of wafer W processing is completed.

In the above-described embodiment, since the curing processing of the interlayer insulating film is performed by irradiating the interlayer insulating film on the wafer W with electron beams with high energy, the period of time required for the curing processing is remarkably reduced as compared to that in the prior art. Besides, electron beams, which are excellent in penetration, reach the inside of the interlayer insulating film to realize uniform curing processing over the entire interlayer insulating film.

Further, since the wafer W processing can be performed in a single wafer processing system, the waiting time of the wafer W as seen in a batch processing system is eliminated, the total processing time of a series of wafer processing is reduced as compared to the prior art. In addition, no waiting time allows the period of time between the pre-heating and the irradiation with the electron beams to be kept almost constant, thus keeping thermal histories of the wafers W uniform among the wafers.

Furthermore, the wafer W is heated by the mounting table 60 in the curing processing of the interlayer insulating film, so that thermal energy can also be supplied to the wafer W to accelerate the curing processing for performance of the curing processing in a shorter time.

Moreover, in the curing processing, since a reduced oxygen atmosphere is maintained with helium gas in the casing 55a, scattering of the electron beams, attenuation of energy, and so on due to oxygen molecules are restrained, whereby irradiation with the electron beams can be preferably performed.

Since the pre-heating is performed in the low temperature heating unit 42 and the high temperature heating unit 48 before performance of the curing processing, the solvent in the coating solution is sufficiently vaporized. This can prevent the solvent from vaporizing in the curing processing to contaminate the electron beam tubes 66 and so on. Besides, the temperature of the pre-heating can be set lower than the heating temperature in the curing processing to gradually increase the temperature of the wafer W. This can prevent cracks, deterioration of the interlayer insulating film, and so on, which occur when the temperature of the wafer W is rapidly increased. It should be noted that the pre-heating in the present embodiment is separately performed at two stages in the low temperature heating unit 42 and the high temperature heating unit 48, but the pre-heating may be performed by heating the wafer W coated with the coating solution only one time at a predetermined temperature. The predetermined temperature in this event is desirably set lower that the heating temperature in the heating processing.

The reduced oxygen atmosphere in the curing processing unit 55 is realized by supplying helium gas thereto in the above embodiment, but it may be realized by reducing the pressure in the processing chamber S of the curing processing unit 55. In this case, the suction pump 69 sucks the atmosphere in the casing 55a through the exhaust pipe 70a and 70b while, for example, the hermeticity of the casing 55a is ensured. This reduces the pressure in the curing processing unit 55 to maintain the reduced oxygen atmosphere therein. It should be noted that a vacuum preliminary chamber (load lock camber) is separately installed at the stage preceding the curing processing unit 55, and the pressure in the vacuum preliminary chamber is set to be higher than the pressure in the curing processing unit 55 and lower than the atmospheric pressure, whereby the period of time for reducing the pressure in the curing processing unit 55 can be reduced.

Alternatively, the reduced oxygen atmosphere may be realized by reducing the pressure while the inside of the casing 55a is being replaced with gas other than oxygen.

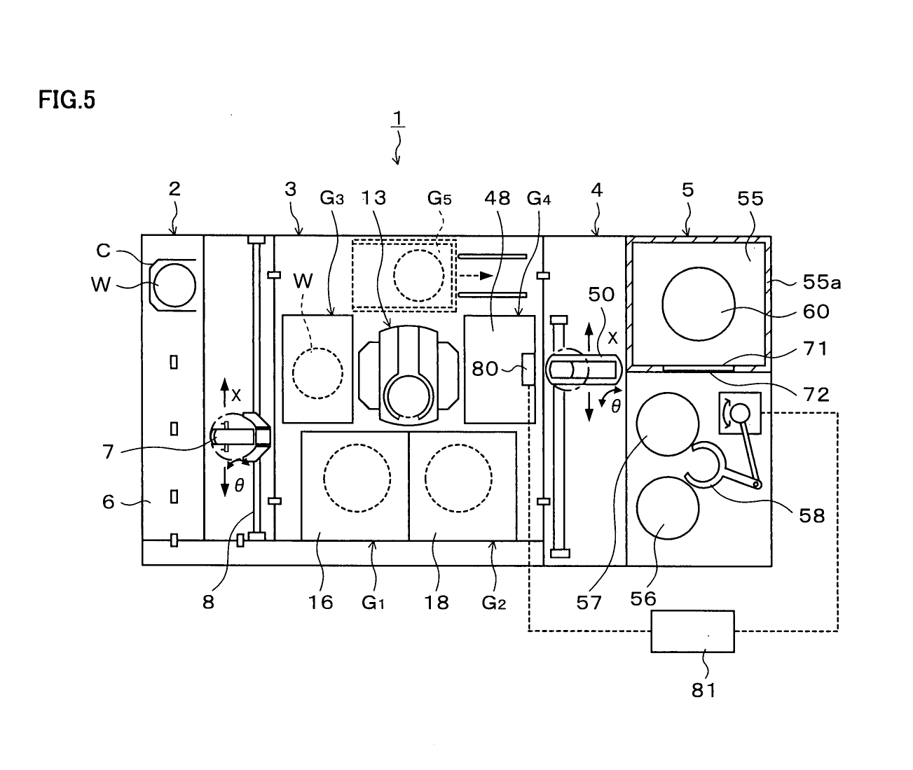

Besides, the period of time between the pre-heating and the electron beam irradiation may be controlled to be more constant in the above-described embodiment. In such a case, for example, as shown in FIG. 5, the high temperature heating unit 48 is provided with a sensor 80 which detects a fact that the wafer W is carried out of the high temperature heating unit 48. The detection signal of the sensor 80 is designed to be outputted to a controller 81 which controls the carrier arm 58. Further, the controller 81 is provided with a timer function which counts a previously set predetermined time. When the detection signal is outputted from the sensor 80 to the controller 81, the timer function starts counting during which the wafer W is carried to the mounting portion 57. Upon the timer function being turned off after a lapse of the set time, the carrier arm 58 holds the wafer W on the mounting portion and carries it into the curing processing unit 55. This keeps the period of time between the completion of the pre-heating and the irradiation with the electron beams more constant, thus keeping the thermal history of the wafer W constant.

Although the wafer W which has undergone the curing processing is returned, as it is, to the cassette station 2 in the above described embodiment, the wafer W may be subjected to post-heating. In this case, for example, the wafer W, which has undergone the curing processing, is once returned to the transfer unit 46 and carried therefrom by the main carrier 13 to, for example, the high temperature heating processing 44 for undergoing heating processing. This heating processing is performed at a temperature higher than the heating temperature in the curing processing, for example, at 300° C. This enables recovery from damage at a lower layer of the interlayer insulating film due to the electron beams, so that the interlayer insulating film improves in insulation performance to form a better interlayer insulating film.

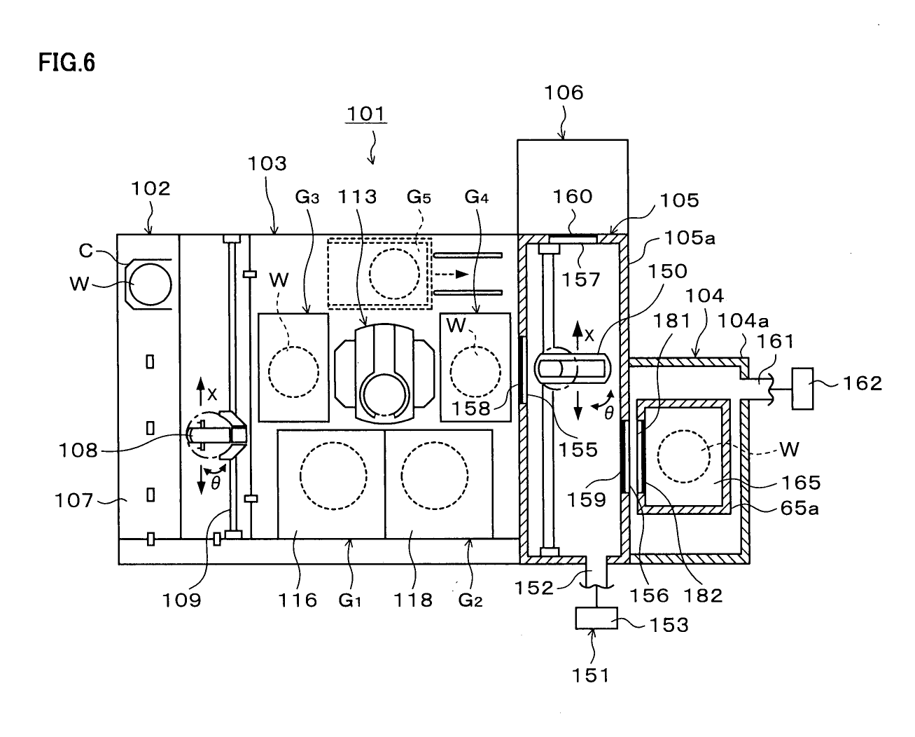

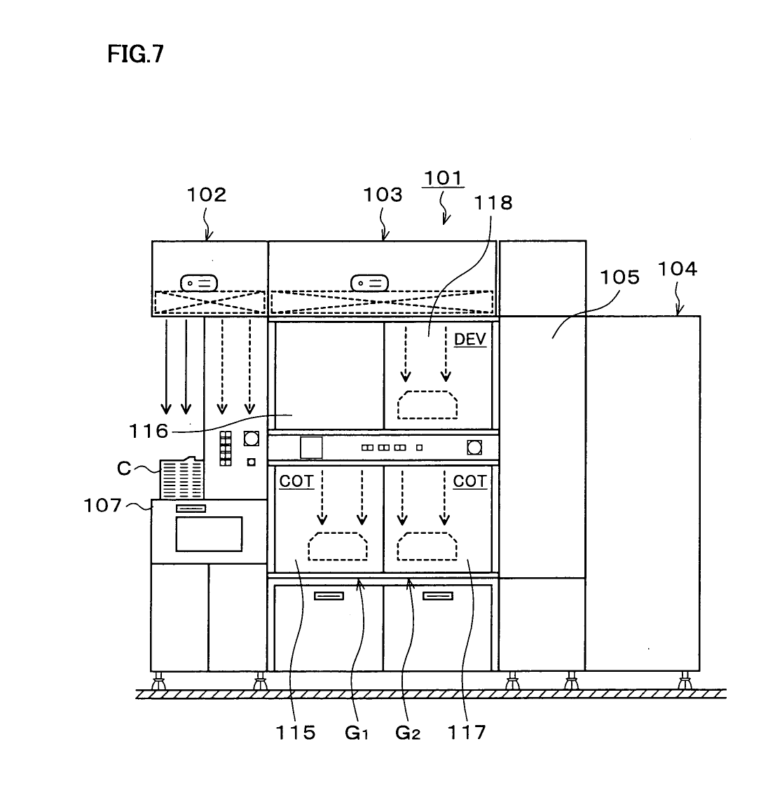

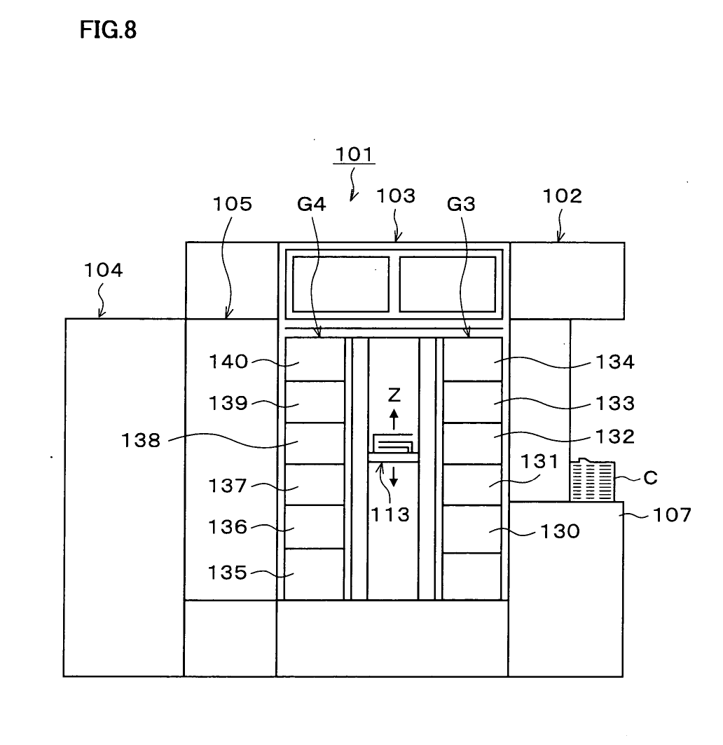

Another preferred embodiment of the present invention will be explained below. FIG. 6 is a plan view showing an outline of a wafer processing apparatus 101 according to this embodiment. FIG. 7 is a front view of the wafer processing apparatus 101, and FIG. 8 is a rear view of the wafer processing apparatus 101.

As shown in FIG. 6, the wafer processing apparatus 101 has a structure in which a cassette station 102 for carrying, for example, 25 wafers W per cassette, as a unit, from/to the outside into/out of the wafer processing apparatus 101 and carrying the wafer W into/out of a cassette C, a first processing station 103 as a first processing section including various kinds of processing units each for performing predetermined processing in a single wafer processing system in a wafer processing process, a second processing station 104 as a second processing section including a single wafer curing processing unit 165 which will be described later, and a carrier chamber 105, placed between the first processing station 103 and the second processing station 104, for carrying the wafer W are integrally connected. Moreover, an exposure processing unit 106 for exposing the wafer W is placed on the rear side of the carrier chamber 105.

In the cassette station 102, a plurality of cassettes C can be mounted at predetermined positions on a cassette mounting table 107, which is a mounting portion, in a line in an X-direction (a top-to-bottom direction in FIG. 6). A wafer carrier 108 which is movable in the direction of arrangement of the cassettes (the X-direction) and in the direction of arrangement of the wafers W housed in the cassette C (a Z-direction; a vertical direction) is provided to be freely movable along a carrier guide 109 so as to be able to selectively get access to the respective cassettes C.

The wafer carrier 108 has an alignment function of aligning the wafer W. The wafer carrier 108 is also structured to be able to get access to a transfer unit 132 included in a third processing unit group G3 on the undermentioned first processing station 103 side.

In the first processing station 103, a main carrier 113 is provided at the center thereof, and various kinds of processing units are stacked in multiple tiers around the main carrier 113 to constitute processing unit groups. In the wafer processing apparatus 101, four processing unit groups G1, G2, G3, and G4 are placed, the first and second processing unit groups Gi and G2 are placed on the front side of the wafer processing apparatus 101, the third processing unit group G3 is placed adjacent to the cassette station 102, and the fourth processing unit group G4 is placed adjacent to the carrier chamber 105. Further, a fifth processing unit group G5 shown by a broken line can be additionally placed on the rear side as an option. The main carrier 113 can carry the wafer W into/out of undermentioned various processing units which are placed in these processing unit groups G1, G2, G3, and G4. It should be noted that the number and placement of processing unit groups are different depending on the type of treatment and processing given to the wafer W, and the number of processing unit groups can be selected freely.

In the first processing unit group G1, as shown in FIG. 7, a coating unit 115 for coating the wafer W with a coating solution which becomes an insulating film and a chemicals storeroom 116 which houses a buffer tank for chemicals and so on are stacked in two tiers from the bottom in order. In the second processing unit group G2, a resist coating unit 117 for coating the wafer W with a resist solution and a developing unit 118 for subjecting the wafer W to developing treatment are stacked in two tiers from the bottom in order.

In the third processing unit group G3, for example, as shown in FIG. 8, cooling units 130 and 131 for cooling the wafer W, a transfer unit 132 for transferring the wafer W from/to the cassette station 102 therethrough, an adhesion unit 133 for enhancing the adhesion between the resist solution and the wafer W, and a post-baking unit 134 for performing heating processing after developing treatment are stacked, for example, in five tires from the bottom in order.

In the fourth processing unit group G4, for example, cooling units 135 and 136, a transfer unit 137 for transferring the wafer from/to the carrier chamber 105 therethrough, a heating processing unit 138 for subjecting the wafer W coated with the coating solution which becomes the insulating film to heating processing, a post-exposure baking unit 139 for subjecting the exposed wafer W to heating processing, and a pre-baking unit 140 for performing heating processing after the coating of the resist solution are stacked, for example, in six tiers from the bottom in order.

The carrier chamber 105 includes a casing 105a which hermetically closes the carrier chamber 105. As shown in FIG. 6, a carrier mechanism 150 for carrying the wafer W between the first processing station 103 and the second processing station 104 is provided inside the carrier chamber 105. The carrier mechanism 150 is structured to be movable in the X-direction (the top-to-bottom direction in FIG. 6) and in the Z-direction (the vertical direction) and rotatable in a θ-direction (a direction of rotation around a Z-axis) so as to be able to get access to the transfer unit 137 included in the fourth processing unit group G4, the undermentioned curing processing unit 165 in the second processing station 104, and the exposure processing unit 106.

In the carrier chamber 105, a pressure reducing mechanism 151 for reducing the pressure in the carrier chamber 105 to a predetermined pressure is provided. The pressure reducing mechanism 151 includes an exhaust pipe 152 for exhausting an atmosphere in the carrier chamber 105 and a suction pump 153 for sucking the atmosphere in the carrier chamber 105 through the exhaust pipe 152 at the predetermined pressure. Hence, it is possible to suck the atmosphere in the carrier chamber 105 and reduce the pressure in the carrier chamber 105 to the predetermined pressure.

The casing 105a of the carrier chamber 105 is provided with a carrier opening 155 for carrying the wafer W from/to the transfer unit 137 therethrough, a carrier opening 156 for carrying the wafer W into/out of the undermentioned curing processing unit 165 therethrough, and a carrier opening 157 for carrying the wafer W into/out of the exposure processing unit 106 therethrough at positions facing the respective processing units. The respective carrier openings 155, 156, and 157 are provided with shutters 158, 159, and 160 for opening and closing the respective carrier openings 155 to 157, respectively, whereby the hermeticity of the carrier chamber 105 can be ensured.

The second processing station 104, similarly to the carrier chamber 105, includes a casing 104a which covers all of the second processing station 104 to enable the second processing station 104 to be hermetically enclosed. The casing 104a is provided with an exhaust pipe 161 for reducing the pressure in the second processing station 104, and the exhaust pipe 161 leads to a suction pump 162 which is free to suck at a predetermined pressure. Hence, all the pressure in the second processing station 104 can be reduced to the predetermined pressure.

In the second processing station 104, the curing processing unit 165 for curing the insulating film on the wafer W by irradiating the wafers W with electron beams one by one is provided. The curing processing unit 165 will be explained in detail below.

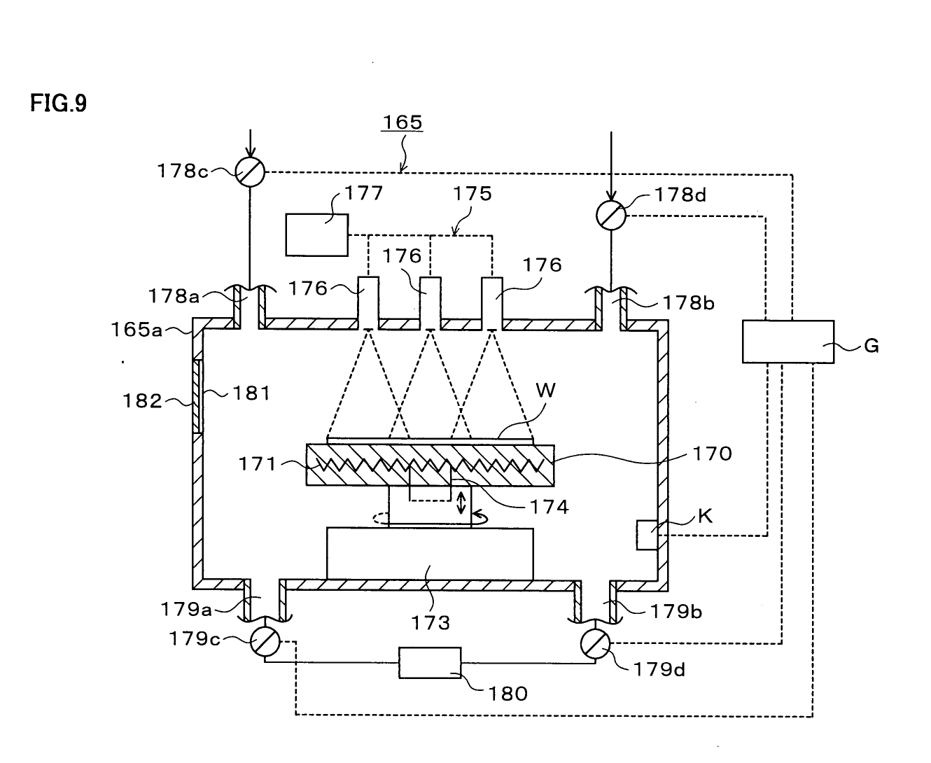

The curing processing unit 165, as shown in FIG. 9, includes a unit casing 165a which covers all of the unit to enable a processing chamber S to be enclosed, whereby a predetermined atmosphere can be maintained in the curing processing unit 165. A mounting table 170 on which the wafer W is mounted is placed in the middle of the unit casing 165a. The mounting table 170 takes the shape of a thick disc, and a material having excellent thermal conductivity, for example, silicon carbide, aluminum nitride, or the like which is ceramic is used as its material.

The mounting table 170 contains, for example, a heater 171 for raising the temperature of the mounting table 170. The heating value of the heater 171 is controlled by a controller not shown, whereby the temperature of the mounting table 170 can be controlled at a predetermined temperature.

A drive mechanism 173 including, for example, a motor for rotating the mounting table 170 is placed under the mounting table 170. Hence, it becomes possible to rotate the mounting table 170 at the time of irradiation with electron beams from undermentioned electron beam tubes 176 to thereby uniformly irradiate the entire surface of the wafer W on the mounting table 170 with the electron beams. Incidentally, the distance between the mounting table 170 and the undermentioned electron beam tubes 176 may be controllable by providing a raising and lowering mechanism, which enables the mounting table 170 to be vertically movable, in the drive mechanism 173.

The mounting table 170 is provided with raising and lowering pins 174 which are protrudable above the mounting table 170 and raise and lower the wafer W while supporting it. Consequently, the wafer W can be freely mounted on the mounting table 170.

The curing processing unit 165 includes an irradiation device 175 for irradiating the wafer W on the mounting table 170 with electron beams. The irradiation device 175 includes plural electron beam tubes 176 each for applying an electron beam and an irradiation controller 177 for controlling output of the electron beams and irradiation time. The electron beam tubes 176 are arranged in positions facing the mounting table 170 in an upper surface of the unit casing 165a. Hence, the electron beams can be applied to the insulating film on the surface of the wafer W from above. The electron beam from each of the electron beam tubes 176 widens as it approaches the wafer W, and the entire surface of the wafer W is irradiated with the electron beams by irradiation from all of the electron beam tubes 176.

In the upper surface of the unit casing 165a, supply pipes 178a and 178b for supplying gas other than oxygen such as an inert gas, helium gas, or nitrogen gas from a supply source not shown into the curing processing unit 165 are provided. The supply pipe 178a is provided on the side of an undermentioned carrier opening 181, and the supply pipe 178b is provided on the opposite side of the undermentioned carrier opening 181. Moreover, the supply pipes 178a and 178b are provided with valves 178c and 178d for regulating the supply quantity of the inert gas, respectively, whereby the supply quantity of the inert gas or the like to be supplied into the unit casing 165a can be regulated. On the other hand, in a lower surface of the unit casing 165a, exhaust pipes 179a and 179b for exhausting the atmosphere in the curing processing unit 165 are provided, and a suction device 180 for sucking the atmosphere in the curing processing unit 165 at a predetermined pressure is connected to the exhaust pipes 179a and 179b. By the aforementioned structure, the inert gas or the like can be substituted in the unit casing 165a, and the pressure therein can be reduced to the predetermined pressure, which creates a reduced oxygen atmosphere in the unit casing 165a.

Moreover, the exhaust pipes 179a and 179b are provided with valves 179c and 179d for regulating exhaust quantity, respectively. The aforementioned valves 178c and 178d, and 179c and 179d are structured in such a manner that their opening and closing can be operated by a control part G. In the unit casing 165a, a detection sensor K for detecting the barometric pressure and oxygen concentration in the unit casing 165a, and obtained detected data can be transmitted to the control part G. Such a structure makes it possible that the data detected by the detection sensor K is transmitted to the control part G and that the control part G operates the valves 178c and 178d and the valves 179c and 179d based on the data. Accordingly, the supply quantity of the inert gas to be supplied into the unit casing 165a and the exhaust quantity to be exhausted to the outside of the unit casing 165a can be regulated, whereby the barometric pressure and oxygen concentration in the unit casing 165a can be controlled at predetermined values. Moreover, when the wafer W is carried in/out through the undermentioned carrier opening 181, the supply quantity from the supply pipe 178a on the carrier opening 181 side can be increased, which makes it possible to compensate for the inert gas which has leaked from the carrier opening 181 and thereby maintain the predetermined atmosphere in the unit casing 165a.

The carrier opening 181 for carrying the wafer W in/out therethrough is placed on the aforementioned carrier mechanism 150 side of the unit casing 165a. This carrier opening 181 is provided with a shutter 182 which makes the carrier opening 181 openable and closable. Hence, the shutter 182 is closed except when the wafer W is carried in/out, whereby the hermeticity inside the unit casing 165a is ensured.

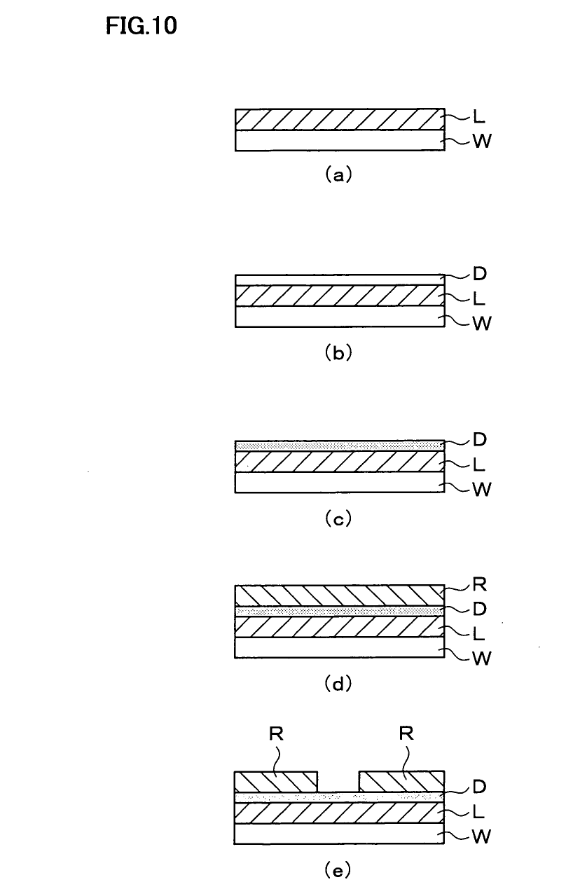

Next, a processing process of the wafer W, which is performed in the wafer processing apparatus 101 structured as above, will be explained. FIG. 10 is an explanatory view of vertical sections of the wafers W each showing a state in which a film is formed on the wafer W in each processing step.

First, before processing is started, the suction pump 162 for reducing the pressure in the second processing station 104 is started, and thereby all the pressure in the second processing station 104 is reduced to a predetermined pressure, for example, 1 Pa to 133 Pa which is higher than the pressure in the curing processing unit 165 at the time of undermentioned curing processing. Furthermore, the suction pump 153 of the carrier chamber 105 is also started, and thereby the pressure in the carrier chamber 105 is reduced to a predetermined pressure, for example, 133 Pa to 1333 Pa which is lower than the atmospheric pressure and higher than the pressure in the second processing station 104.

The wafers W (FIG. 10 (a)), for example, on the surface of each of which a Low-k film (organic silicon oxide film) L is formed, are set in the cassette C in the cassette station 102, and when the wafer processing is started, the wafers W are carried one by one to the transfer unit 132 by the wafer carrier 107. Subsequently, the wafer W is carried by the main carrier 113 to the cooling unit 130 where temperature control is performed. Then, the wafer W is carried to the coating unit 115 by the main carrier 113 and coated with a predetermined coating solution, for example, a coating solution containing MSQ (methyl silsesquioxane) which becomes an interlayer insulating film D. Such coating processing is performed, for example, by rotating the wafer W at a predetermined speed and supplying the coating solution to the center portion of the wafer W which is being rotated. The supplied coating solution is spread over the entire surface of the wafer W by centrifugal force, and thereby a solution film is formed on the wafer W.

The wafer W coated with the coating solution is then carried to the heating processing unit 138 and subjected to heating processing for vaporizing a solvent in the coating solution. At this time, the wafer W is heated, for example, at 200° C. for two minutes. Hence, the solvent in the coating solution is removed by vaporization, and the interlayer insulating film D having a predetermined thickness is formed on the wafer W (FIG. 10 (b)).

Thereafter, the wafer W is carried to the transfer unit 137 by the main carrier 113. The shutter 158 of the carrier chamber 105 is then opened, and the wafer W is carried through the carrier opening 155 into the carrier chamber 105, the pressure in which is reduced, by the carrier mechanism 150. Subsequently, the shutter 159 of the carrier chamber 105 and the shutter 182 of the curing processing unit 165 are opened, and the wafer W is carried into the curing processing unit 165 maintained at 1 Pa to 133 Pa.

Now, the operation of the curing processing unit 165 will be explained. First, before the wafer W is carried into the curing processing unit 165, the heating value of the heater 171 is controlled by the controller not shown, whereby the temperature of the mounting table 170 is controlled, for example, at 250° C. which is higher than the heating temperature of the aforementioned heating processing unit 138.

Then, when being carried into the unit casing 165a through the carrier opening 181 by the carrier mechanism 150, the wafer W is moved to a position above the center portion of the mounting table 170, and delivered to the raising and lowering pins 174 which rise and stand by in advance. Subsequently, the carrier mechanism 150 withdraws from within the unit casing 165a, and the shutter 182 is closed. The wafer W is then lowered with the lowering of the raising and lowering pins 174, and mounted on the mounting table 170. Hence the temperature of wafer W is raised by the mounting table 170. At this time, helium gas, for example, is supplied into the unit casing 165a from the supply pipes 178a and 178b, and the atmosphere in the unit casing 165a is exhausted from the exhaust pipes 179a and 179b. The pressure in the unit casing 165a is monitored by the detection sensor K, and based on obtained detected data, the valves 178c and 178d and the valves 179c and 179d are operated by the control part G. Consequently, the helium gas is substituted in the unit casing 165a, and the pressure in the unit casing 165a is reduced to a predetermined pressure, for example, a pressure in the range of 1 Pa to 133 Pa which is lower than the pressure in the second processing station 104. As a result, an atmosphere with a low oxygen concentration, for example, an oxygen concentration of 1 ppm to 10 ppm or lower is maintained in the unit casing 165a.

When the temperature of the wafer W on the mounting table 170 is stabilized at 250° C. after a lapse of a predetermined period of time, the wafer W is rotated at a low speed by the drive mechanism 173. Thereafter, as shown in FIG. 9, the interlayer insulating film D on the surface of the wafer W is irradiated with an electron beam at a predetermined output, for example, 10 keV from each of the electron beam tubes 176 for a predetermined period of time, for example, approximately two minutes. Hence, energy of the electron beams is supplied to the interlayer insulating film D to induce macromolecular polymerization of the MSQ which forms the interlayer insulating film D, and thereby the interlayer insulating film D is cured. (FIG. 10 (c)). Incidentally, the output and irradiation time of the electron beams are set appropriately according to film thickness, processing atmosphere, and the like.

When the irradiation with electron beams for approximately two minutes is completed, the rotation of the mounting table 170 is stopped, and the mounting table 170 is raised again by the raising and lowering pins 174. At this time, the supply of the helium gas and the pressure reduction in the unit casing 165a are stopped. Then, the shutter 182 is opened, the carrier mechanism 150 goes into the unit casing 165a again, the wafer W is delivered to the carrier mechanism 160, and thus the curing processing of the interlayer insulating film D is completed.

The wafer W which has undergone the curing processing is carried to the transfer unit 137 by the carrier mechanism 150. Subsequently, it is carried into the adhesion unit 133 included in the third processing unit group G3 by the main carrier 113. In this adhesion unit 133, an adhesion promoter such as HMDS for enhancing adhesion to the resist solution is applied onto the wafer W. Then, the wafer W is carried to the cooling unit 131 by the main carrier 113 and cooled to a predetermined temperature. Thereafter, the wafer W is carried to the resist coating unit 117 and coated with the resist solution, and thereby a resist film R is formed (FIG. 10 (d)). The wafer W coated with the resist solution is carried to the pre-baking unit 140 and the cooling unit 136 in sequence, and undergoes predetermined thermal processing in each unit. Thereafter, the wafer W is carried to the transfer unit 137.

Subsequently, the wafer W is carried into the carrier chamber 105 by the carrier mechanism 150, and carried to the exposure processing unit 106 via the carrier chamber 105. The wafer W is subjected to exposure processing in a predetermined pattern there, and the wafer W which has undergone the exposure processing is returned again to the transfer unit 137 by the carrier mechanism 150. The wafer W returned to the transfer unit 137 is carried to the post-exposure baking unit 139 and the cooling unit 135 in sequence by the main carrier 113, and after subjected to thermal processing, the wafer W is carried to the developing unit 118.

The wafer W carried to the developing unit 116 is supplied with a developing solution and developed for a predetermined period of time. Thereby, part of the resist film R on the wafer W is dissolved (FIG. 10 (e)). The wafer W which has undergone developing treatment is carried to the post-baking unit 134 and the cooling unit 130 in sequence by the main carrier unit 113, and subjected to predetermined thermal processing. Thereafter, the wafer W is returned to the cassette C via the transfer unit 132 by the wafer carrier 108, and a series of wafer processing in the wafer processing apparatus 101 is completed.

In the aforementioned embodiment, the curing processing unit 165 which performs curing processing of the interlayer insulating film by irradiation with electron beams is provided in the wafer processing apparatus 101, whereby the curing processing can be performed in a short period of time, and a reduction in TAT of the whole wafer processing is achieved. Moreover, since a single wafer processing system is adopted, unlike a conventional batch processing system, the waiting time of the wafer W before and after the curing processing is eliminated, whereby a reduction in TAT is also achieved.

Moreover, the pressure of the atmosphere in the curing processing unit 165 can be reduced, which prevents the applied electron beams from scattering, and consequently the interlayer insulating film D can be effectively irradiated with stronger electron beams. As a result, irradiation time can be reduced, leading to a reduction in curing processing time.

Further, the heating processing unit 138 for subjecting the wafer W to heating processing is placed in the first processing station 103, whereby before the curing processing is performed by the curing processing unit 165, the solvent in the coating solution which becomes the interlayer insulating film D can be suitably vaporized in the first processing station 103. This eliminates the need for vaporizing the solvent when the curing processing is performed, which prevents the electron beam tubes 176 and the like from being contaminated by the solvent.

The resist coating unit 117 and the developing unit 118 are provided in the first processing station 103, and the exposure processing unit 106 is provided adjacent to the wafer processing apparatus 101, whereby a photolithography process in which the wafer W is coated with the resist solution, exposed in the predetermined pattern, and subjected to developing treatment can be performed continuously in the same wafer processing apparatus 101. As a result, the photolithography process which is conventionally performed in a separate apparatus is inlined, which results in a reduction in a total processing time required for a series of processing.

Further, the pressures in the carrier chamber 105 and the second processing station 104 can be reduced by the pressure reducing mechanism 151, the suction pump 162, and the like, whereby the reduced oxygen atmosphere can be maintained in a carrier path of the wafer W from the heating processing unit 138 for vaporizing the solvent in the coating solution to the curing processing unit 165. Consequently, the oxidation of the interlayer insulating film D on the wafer W during carriage between them is prevented. Furthermore, the pressure in the second processing station 104 is made lower than the pressure in the carrier chamber 105 and higher than the pressure in the curing processing unit 165 at the time of curing processing, whereby the pressure reduction increases in order of the carrier chamber 105, the second processing station 104, and the curing processing unit 165, and hence the highly reduced pressure in the curing processing unit 165 becomes easy to maintain, resulting in a reduction in pressure reduction time. Moreover, the pressure on the carried wafer W can be reduced gradually from the atmospheric pressure, whereby a burden imposed on the wafer W due to pressure change can be lightened.

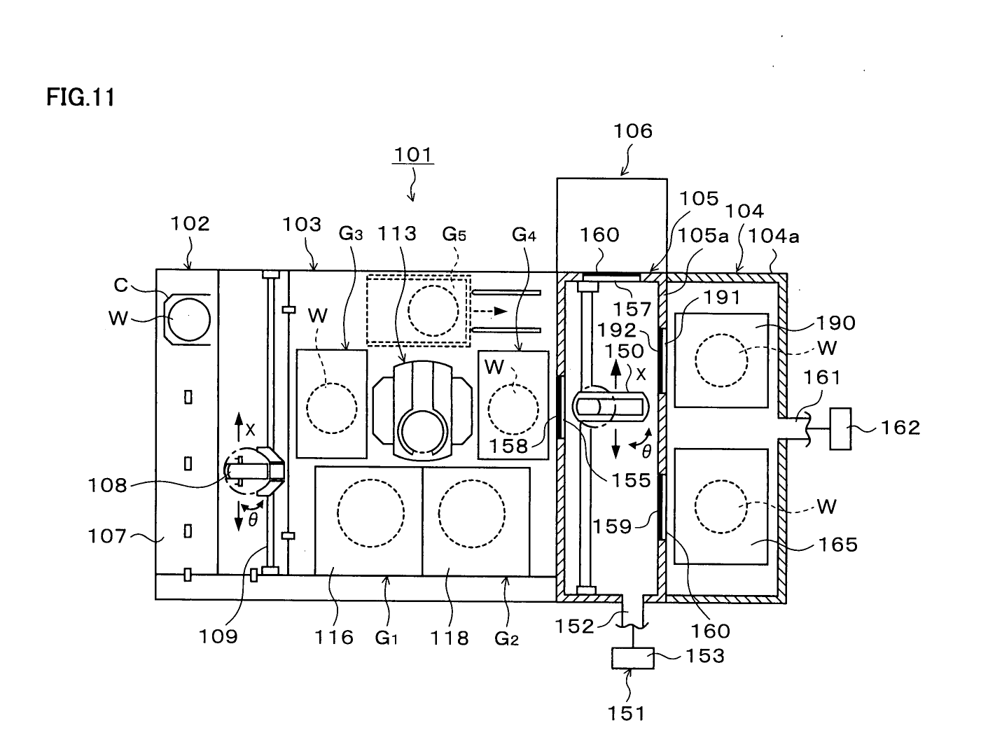

As shown in FIG. 11, an etching unit 190 for subjecting the wafer W to etching processing in a reduced pressure atmosphere may be provided in the second processing station 104 described in the above embodiment. In this case, a carrier opening 191 for carrying the wafer W therethrough and a shutter 192 which opens and closes the carrier opening 191 are placed at a position facing the etching unit 190 of the casing 105a. By such a structure, an etching processing process of selectively removing the interlayer insulating film D in accordance with a resist pattern can be inlined, leading to a reduction in the total processing time of wafer processing. Moreover, the etching processing is performed in an extremely highly reduced pressure atmosphere, and as described above, for example, the pressure can be reduced gradually in order of the carrier chamber 105 and the second processing station 104, whereby pressure reduction time can be reduced, and the burden imposed on the wafer W due to pressure change can be lightened.

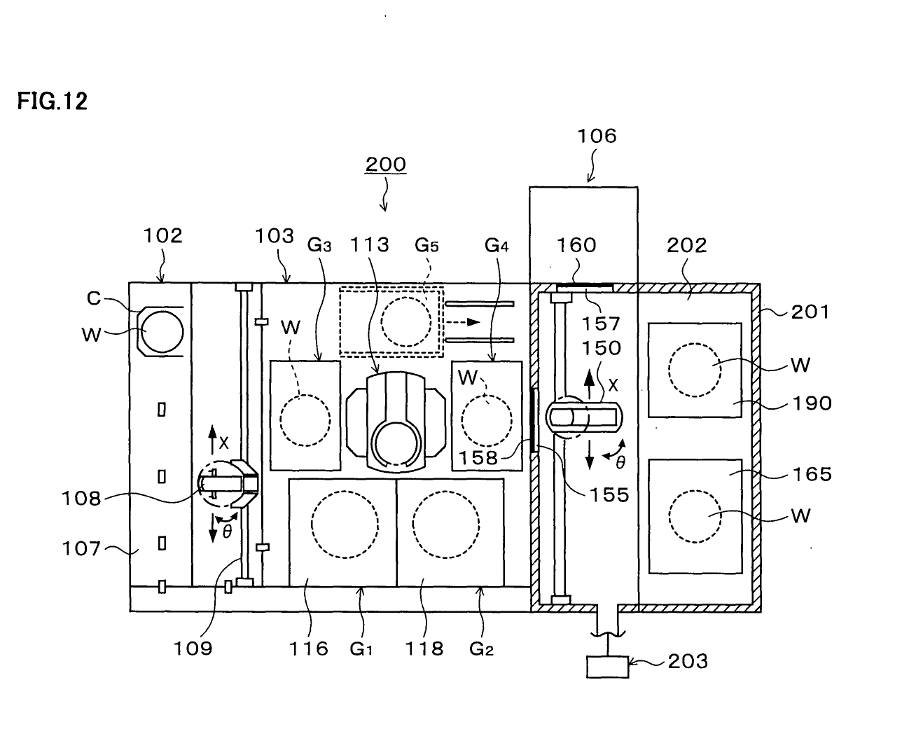

Although the pressures in a carrying area of the carrier mechanism 150 and in the second processing station 104 are separately reduced, it is also suitable to provide a reduced pressure chamber housing both the carrier mechanism 150 and the second processing station 104 and reduce the pressure therein. In such a case, for example, as shown in FIG. 12, a casing 201 capable of housing all of the carrier mechanism 150 and the second processing station 104 and placing both of them in a hermetically closed space is provided in a wafer processing apparatus 200 to thereby form a reduced pressure chamber 202. A pressure reducing mechanism 203 for reducing the pressure in the casing 201 to a predetermined pressure is connected to the casing 201. Thereby, the pressures in the area in which the wafer W is carrier by the carrier mechanism 150 and in the second processing station 104 can be controlled by only the single pressure reducing mechanism 203. Further, the pressure in the reduced pressure chamber 202 can be controlled at a pressure lower than the atmospheric pressure and higher than the pressures in the curing processing unit 165 at the time of curing processing and the etching unit 190. Accordingly, the pressure difference between outside and inside the curing processing unit 165 and the etching unit 190 is reduced, whereby the pressures in the curing processing unit 165 and the etching unit 190 become easy to maintain, and besides the pressure reduction time can be reduced. Moreover, the pressure on the wafer W carried to the etching unit 190 or the like in which the pressure is highly reduced is reduced stepwise, whereby the burden imposed on the wafer W due to pressure change can be lightened.

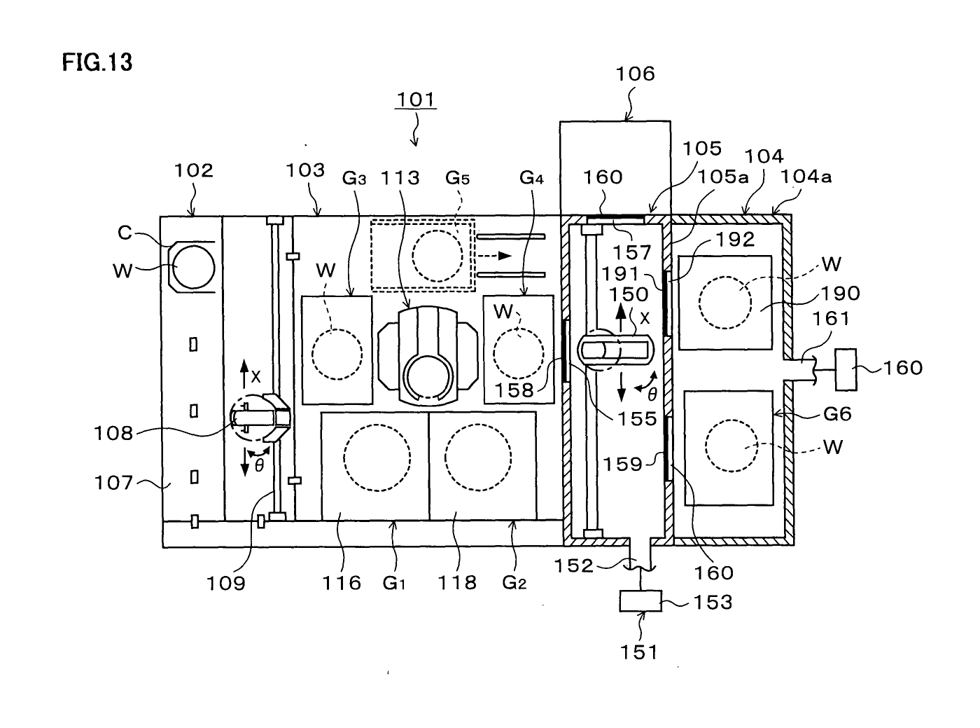

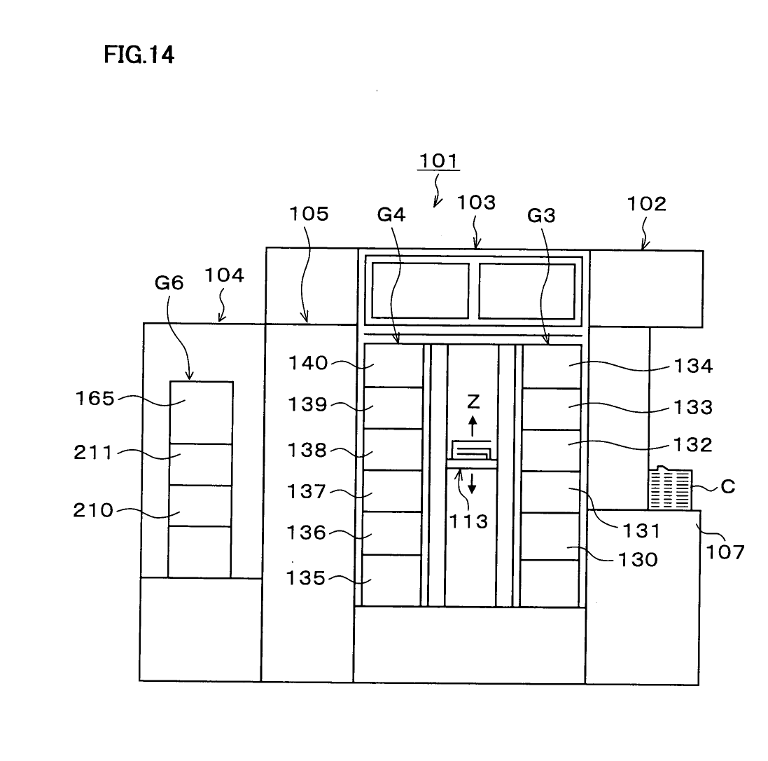

Additionally, a thermal processing unit for subjecting the wafer W to thermal processing may be provided in the second processing station 104 described in the above embodiment. In such a case, for example, in the second processing station 104, a sixth processing unit group G6 in which plural processing units can be mounted in multiple tiers as shown in FIG. 13 and FIG. 14 is provided. In the sixth processing unit G6, a cooling unit 210 and a heating unit 211 as thermal processing units and the curing processing unit 165 are stacked from the bottom in order. The wafer W which has undergone curing processing in the curing processing unit 165 is carried to the heating unit 211 by the carrier mechanism 150 and subjected to heating processing. At this time, the wafer W is heated, for example, at a temperature which is higher than a heating temperature of 250° C. in the curing processing unit 165, for example, at 300° C. to 400° C. The wafer W is then carried to the cooling unit 210 and cooled, for example, to a normal temperature, for example, 23° C. The wafer W which has undergone cooling processing is then carried, for example, to respective processing units in the first processing station 103 as described above and subjected to predetermined photolithography processing. As stated above, by subjecting the wafer W which has undergone curing processing to thermal processing, the film quality of the interlayer insulating film D on the wafer W is improved, leading to the formation of the more proper interlayer insulating film D.

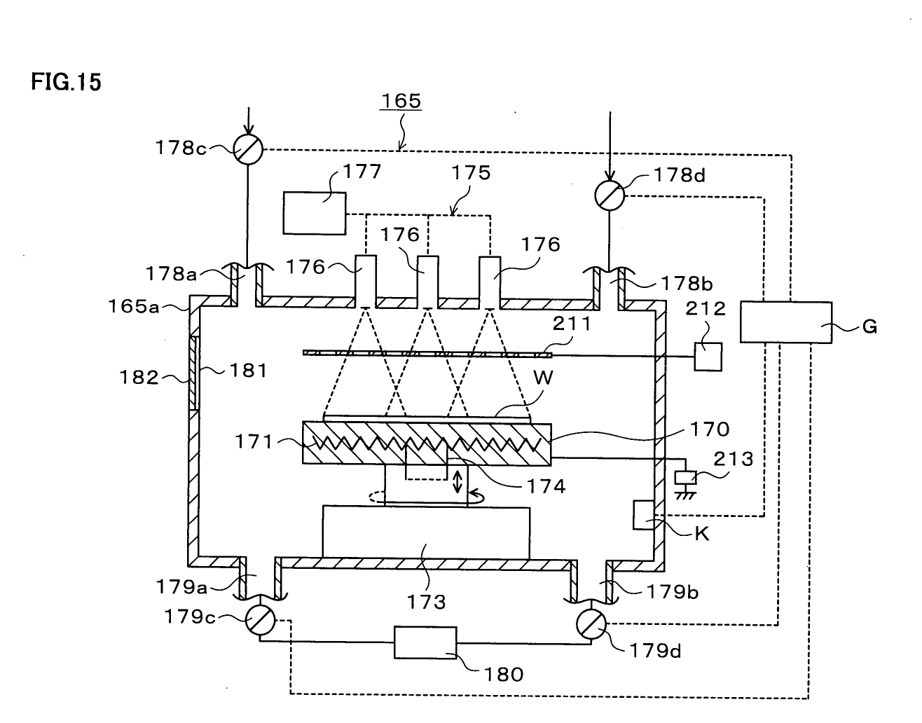

Next, another embodiment will be explained. FIG. 15 shows another example of the curing processing unit 165, and a grid electrode 211 is placed in a unit casing 165a forming a processing chamber S in this example. The grid electrode 211 is positioned between electron beam tubes 176 and a mounting table 170. To the grid electrode 211, a predetermined electric power is supplied from a power source 212. A predetermined voltage is applied to the mounting table 170 from a power source 213, and a reverse bias voltage is applied to a wafer W on the mounting table 170.

According to the curing processing unit 165, when electron beams from the electron beam tubes 176 pass through the grid electrode, the speed of the electron beams is reduced, or the number of electrons passing therethrough is decreased, whereby the energy of electron beams reaching the wafer W can be controlled. Accordingly, it is possible to appropriately cure the insulating film at a predetermined depth regardless of the thickness of the insulating film applied on the wafer W. For example, the control conducted in such a manner that the energy is reduced when the insulating film to be cured is thin, and the energy is not reduced when the insulating film to be cured is thick, enables an appropriate curing processing. The control is effective in the curing processing of a multilayer insulating film.

By applying a reverse bias voltage to the mounting table 170 for the wafer W, the incident speed of the electron beams can also be reduced. Accordingly, the power source 213 can be adjusted to control the energy of the electron beams reaching the wafer W.

From the above, the control of both the grid electrode 211 and the power source 213 enables more precise control.

By the way, when the curing processing with electron beams is performed, the wafer W may be charged up. The wafer W which is charged up beyond an allowable range can cause product defects. Therefore, it is preferable to generate plasma in the unit casing 165a as required after the completion of the curing processing with electron beams, so that the potential of the charged-up wafer W is lowered by the plasma.

As a source of generating the plasma, the electron beams tubes 176 can be used as they are. To facilitate the generation of plasma, Ar (argon) gas is preferably introduced into the unit casing 165a.

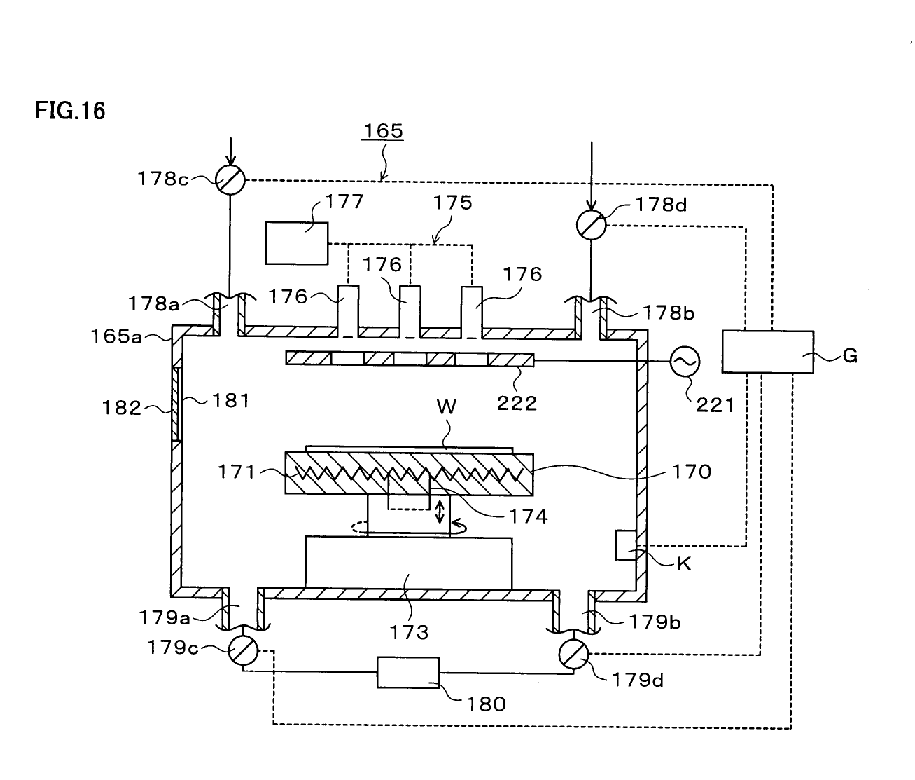

Further, if direct irradiation of the wafer W when the plasma is generated by the electron beams is unfavorable, the irradiation angle of the electron beams may be changed, or a plasma generator 222 such as an electrode, antenna, or the like which generates plasma by a high frequency from a high-frequency power source 221 may be placed in the unit casing 165a as shown in FIG. 16.

In ordinal curing processing even for a multiplayer insulating film has been conventionally performed in such a manner that after a coating solution which becomes a material of the insulating film is applied, curing processing is performed by heating, thereafter another coating solution which becomes a material of the insulating film is applied, and then curing processing is again performed by heating. As has been described, a wafer to be cured has been carried into a heating furnace of a batch-processing system every time and subjected to curing processing by long-time heating.

According to the invention in this application, in this viewpoint, because of the curing processing with electron beams, the curing processing can be performed in a period of time much shorter than that in the prior art.

In the curing processing with electron beams, however, the film thickness is not directly proportional to the curing processing time due to the adjustment of the energy of electron beams. Therefore, for example, after a first coating solution is applied, pre-heating just for vaporizing the solvent, which can be called soft-baking, is performed, directly thereafter a next coating solution is applied, and then the curing processing with electron beams is performed as it is, whereby more efficient processing can be performed for curing the multilayer insulating film.

It should be noted that the wafer W which has undergone developing treatment is irradiated with electron beams, so that the film formed in the lithography process can be enhanced.

Incidentally, although the unit for forming the interlayer insulating film, the unit for subjecting this interlayer insulating film to curing processing, and the units for performing photolithography processing are mounted in the wafer processing apparatus in the above embodiment, only the unit for forming the interlayer insulating film and the unit for performing curing processing by means of electron beams may be mounted in the wafer processing apparatus. Also in this case, a reduction in TAT can be achieved as compared with conventional arts in which curing processing is performed in a batch processing system.

In the above embodiment, the present invention is applied to an SOD interlayer insulating film, but the present invention can be applied to wafer processing for other interlayer films, for example, an SOG (spin on glass), a Low-k film (organic silicon oxide film), a resist film, and so on.

The present invention is also applicable, for example, to a film formed by CVD (Chemical Vapor Deposition). More specifically, formation of the insulating film that constitutes the interlayer insulating film is performed by applying the coating solution in the coating unit in the above-described embodiment, but the formation of the interlayer insulating film may be performed by, instead of the application of the coating solution, irradiating an insulating film formed by a CVD process with electron beams.

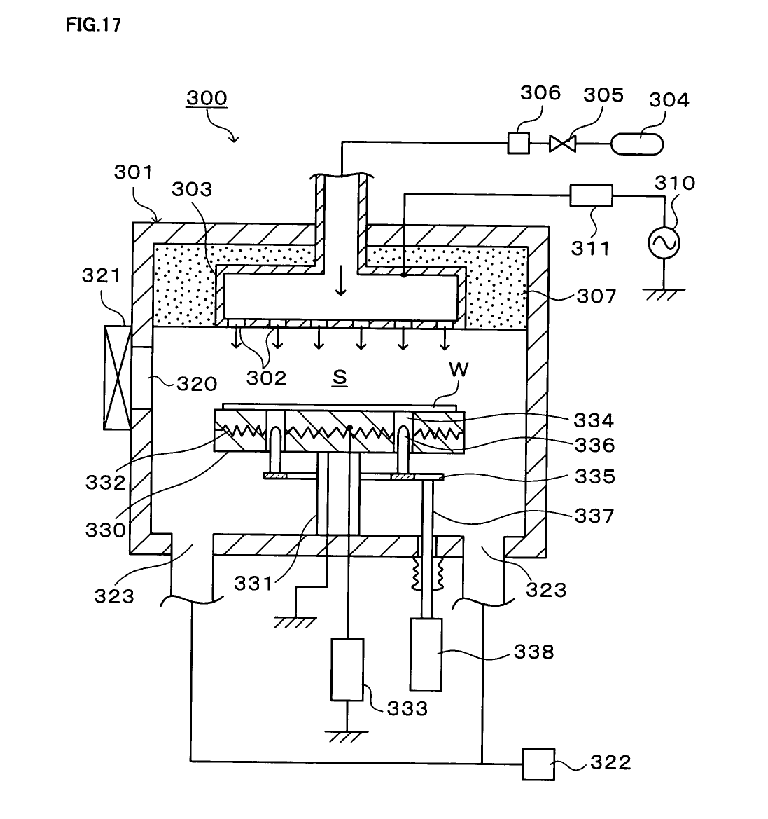

FIG. 17 shows a CVD unit usable in place of the coating unit, for example, a plasma CVD unit 300.

This plasma CVD unit 300 includes a processing casing 301 which is cylindrically molded, for example, of aluminum. At a lower surface of a ceiling portion of the processing casing 301, a shower head portion 303 having many gas blowout ports 302 is provided. From a gas supply source 304, a film forming gas, for example, a silane-based film forming gas can be lead to a processing space S in the processing casing 301 through a valve 305 and a massflow controller 306.

The shower head portion 303 is formed of a dielectric to also serve as an upper electrode. The outer periphery and upper side of the shower head portion 303 are entirely covered with an insulator 307 so that the shower head portion 303 is insulated from the processing casing 301. To the shower head portion 303, a high frequency, for example, of 13.56 MHz is applied from a high-frequency power source 310 via a matching circuit 311.

The processing casing 301 is formed, at its side wall, with a carrier opening 320 for carrying the wafer, and the carrier opening is provided with an openable/closable gate valve 321. At the bottom portion of the processing casing 301, exhaust ports 323 connected to a vacuum pump 322 are provided to be able to reduce the pressure in the processing casing 301 to an arbitrary pressure level.

In the processing casing 301, a mounting table 330 on which a semiconductor wafer W is mounted is supported by a column 331. The mounting table 330 also serves as a lower electrode so that plasma is generated by the aforementioned high frequency in the processing space S between the mounting table 330 and the shower head portion 303 being the upper electrode. Inside the mounting table 330, a heater 332 is contained in a predetermined pattern arrangement. The heater 332 can heat the wafer W on the mounting table 330 to an arbitrary temperature up to, for example, 300° C. using power from a heater power source 333.

The mounting table 330 is provided with a plurality of pin holes 334 therethrough in the top-to-bottom direction, and in the respective pin holes 334, pins 336 which are connected in common to a connecting member 335 are accommodated in a loosely fittable state. The connecting member 335 is connected to a top end of a rod 337 which is vertically movable through the bottom portion of the casing, and a lower end of the rod 337 is connected to a cylinder 338. Therefore, operation of the cylinder 338 enables the pins 336 to protrude above the mounting table 330 so as to transfer the wafer W to/from the mounting table 330.

According to the plasma CVD unit 300 having the above-described structure, for example, organosilicon and silicon oxide, F-containing SiO, and SiOC (carbon-containing silicon oxide) insulating films can be formed by the CVD process on the surface of the wafer W on the mounting table 330.

As described above, the insulating film formed by the CVD process has a film quality finer than that formed by application of the coating solution. By irradiating the insulating film formed by the CVD process with electron beams, for example, in the curing processing unit 55, an insulating film can be formed which is stronger and better in quality.

It should be noted that the plasma CVD unit 300 is installable in the insulating film forming apparatus 1 in place of, for example, the above-described coating units 16 and 18.

Furthermore, the embodiments explained above are applied to the processing method of the wafer in an interlayer insulating film forming process of semiconductor wafer device manufacturing processes, but the present invention can be also applied to a processing method for substrates other than the semiconductor wafer, for example, an LCD substrate.

The present invention is useful in forming an interlayer insulating film on a wafer or an LCD glass substrate in manufacturing processes of a semiconductor device or an LCD substrate in a multilevel interconnection structure.

What is claimed is:

1. A substrate processing method, comprising the steps of:
forming an interlayer insulating film on a substrate; and
irradiating the interlayer insulating film on the substrate with electron beams in a processing chamber to cure the interlayer insulating film.

2. The substrate processing method as set forth in claim 1, wherein
in said step of curing the interlayer insulating film, the substrate is heated to a predetermined temperature.

3. The substrate processing method as set forth in claim 1, wherein
said step of curing the interlayer insulating film is performed in a reduced oxygen atmosphere with an oxygen concentration lower than that of at least an atmospheric air.

4. The substrate processing method as set forth in claim 1, wherein
said step of forming the interlayer insulating film comprises a step of coating the substrate with a coating solution which becomes the interlayer insulating film; and
between said coating step and said step of curing the interlayer insulating film, a pre-heating step of heating the substrate is performed.

5. The substrate processing method as set forth in claim 1, further comprising:
a post-heating step of heating the substrate after said step of curing the interlayer insulating film.

6. The substrate processing method as set forth in claim 1, further comprising: the step of
generating plasma in the processing chamber after irradiating with the electron beams to cure the interlayer insulating film.

7. The substrate processing method as set forth in claim 2, wherein
the reduced oxygen atmosphere is created by replacing at least an atmosphere around the substrate with a gas of molecular weight lower than that of oxygen.

8. The substrate processing method as set forth in claim 2, wherein
the reduced oxygen atmosphere is created by reducing a pressure in the processing chamber.

9. The substrate processing method as set forth in claim 4, wherein
a period of time between completion of said pre-heating step and irradiation of the substrate with the electron beams is controlled to be constant.

10. The substrate processing method as set forth in claim 4, wherein
said pre-heating is performed at a temperature lower than a temperature of the substrate in said step of curing the interlayer insulating film.

11. The substrate processing method as set forth in claim 5, wherein
said post-heating is performed at a temperature higher than the temperature of the substrate in said step of curing the interlayer insulating film.

12. The substrate processing method as set forth in claim 6, wherein
the plasma is generated by irradiation with the electron beams.

13. The substrate processing method as set forth in claim 6, wherein
the plasma is generated by supply of high-frequency power.

14. A substrate processing method, comprising the steps of:
repeating both a coating step of coating a substrate with a coating solution which becomes an interlayer insulating film and a pre-heating step of heating the substrate after said coating step; and
after a final coating step, irradiating a plurality of interlayer insulating films on the substrate with electron beams in a processing chamber to concurrently cure the plurality of interlayer insulating films.

15. A substrate processing method, comprising the steps of:
forming an insulating film on a substrate by a CVD process; and
irradiating the insulating film on the substrate with electron beams in a processing chamber to process the insulating film.

16. The substrate processing method as set forth in claim 15, wherein
the substrate is heated to 200° C. or higher in said step of processing the insulating film.

17. The substrate processing method as set forth in claim 15, further comprising:
a post-heating step of heating the substrate after said step of irradiating with electron beams to process the insulating film.

18. The substrate processing method as set forth in claim 15, further comprising: the step of
generating plasma in the processing chamber after irradiating with the electron beams to process the insulating film.

19. A substrate processing apparatus, comprising:
a first processing section having a coating unit for coating a substrate with a coating solution which becomes an insulating film;
a second processing section having a curing processing unit for curing the insulating film on the substrate by irradiating the substrates one by one with electron beams; and
a carrier mechanism for carrying the substrate between said first processing section and said second processing section.

20. The substrate processing apparatus as set forth in claim 19, wherein
said curing processing unit includes a grid electrode between a mounting table on which the substrate is mounted and a device for irradiating with the electron beams.

21. The substrate processing apparatus as set forth in claim 19, wherein
said curing processing unit includes a mounting table on which the substrate is mounted, and said mounting table is capable of applying a reverse bias voltage to the substrate.

22. The substrate processing apparatus as set forth in claim 19, wherein
said curing processing unit is structured so that the pressure in said curing processing unit is allowed to be reduced.

23. The substrate processing apparatus as set forth in claim 19, wherein
said first processing section includes a heating processing unit for subjecting the substrate coated with the coating solution to heating processing.

24. The substrate processing apparatus as set forth in claims 19, wherein
said first processing section further includes a resist coating unit for coating the substrate with a resist solution and a developing unit for subjecting the substrate to developing treatment,
an exposure processing unit for exposing the substrate is provided in an area where the substrate is allowed to be carried by said carrier mechanism.

25. The substrate processing apparatus as set forth in claims 19, further comprising:
a carrier chamber housing said carrier mechanism and being hermetically closable; and
a pressure reducing mechanism for reducing the pressure in said carrier chamber to a predetermined pressure.

26. The substrate processing apparatus as set forth in claims 19, wherein
the pressure in said second processing section is allowed to be reduced.

27. The substrate processing apparatus as set forth in claims 19, further comprising:
a reduced pressure chamber housing said carrier mechanism and said second processing section and being hermetically closable; and
a pressure reducing mechanism for reducing the pressure in said reduced pressure chamber to a predetermined pressure.

28. The substrate processing apparatus as set forth in claims 19, wherein
a thermal processing unit for subjecting the substrate to thermal processing is provided in said second processing section.

29. The substrate processing apparatus as set forth in claim 24, wherein
an etching unit for subjecting the substrate to etching processing in a reduced pressure atmosphere is provided in said second processing section.

30. A substrate processing apparatus, comprising:
a first processing section having a CVD unit for forming an insulating film on a substrate by a CVD process;
a second processing section having a curing processing unit for curing the insulating film on the substrate by irradiating the substrates one by one with electron beams; and
a carrier mechanism for carrying the substrate between said first processing section and said second processing section.
